(19) United States
(12) Patent Application Publication
(10) Pub. No.: US 2006/0021737 A1
(43) Pub. Date: Feb. 2, 2006

(54) Liquid cooling device

(75) Inventors: Hsieh-Kun Lee, Tu-Cheng (TW); Cheng-Tien Lai, Tu-Cheng (TW); Zhi-Yong Zhou, Shen-Zhen (CN)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: Foxconn Technology Co., Ltd., Tu-Cheng City (TW)

(21) Appl. No.: 11/168,069

(22) Filed: Jun. 28, 2005

(30) Foreign Application Priority Data
Jul. 31, 2004 (CN) 200410050971.3

(51) Int. Cl. H05K 7/20

(52) U.S. Cl. 165/80.4; 165/104.33; 361/699

(57) ABSTRACT

A liquid cooling device includes a hollow heat absorbing unit (2) containing liquid therein, a first heat exchange body (32) and a second heat exchange body (34). The first heat exchange body defines isolated first and second rooms (330, 331) therein. The second heat exchange body defines flow-communicated first and second chambers (350, 351) therein. The first chamber is communicated to the first room, and the second chamber is communicated to the second room. The liquid cooling device further includes a pump (4) fluidly connected between the heat absorbing unit and the second room, and a pipe (7) fluidly connecting the heat absorbing unit and the first room.

### BACKGROUND

1. Field

The present invention relates to a cooling device for removing heat from heat-generating electronic devices, and more particularly to a liquid cooling device.

2. Related Art

Over the past few years, CPU speeds have been increasing at a dramatic rate. In order to generate the new speeds, CPUs have more transistors, are drawing more power and have higher clock rates. This leads to greater heat produced by the CPU in the computer. The waste heat can accumulate and generate unacceptable high temperature and thermal stress on CPU, resulting in reliability performance degradation and system malfunction. Heat sinks have been added to all modem PC CPUs to help try to alleviate some of the heat from the processor into the surrounding environment, but as the fans get louder and larger new solutions are being looked into, namely liquid cooling.

Liquid cooling is essentially a radiator for the CPU inside of the computer. A liquid cooling system circulates a liquid through a cold plate attached to the processor inside of the computer. As the liquid passes through the cold plate, heat is transferred from the hot processor to the cooler liquid. The hot liquid then moves out to a heat sink at proper place and transfers the heat to the ambient air flowing through the heat sink. The cooled liquid then travels back through the system to the CPU to continue the process.

A typical liquid cooling system generally comprises a cold plate, a pump, a heat-dissipating fin, a delivery pipe and a supply pipe having a serpentine configuration. The pump draws the working liquid from the cold plate via the delivery pipe, and supplies the working liquid back to the cold plate via the supply pipe. The supply pipe is mounted on the heat-dissipating fin such that the working liquid is cooled while passing the supply pipe. However, the typical liquid cooling system has several drawbacks. Since only a small section of the supply pipe is in contact with the heat-dissipating fin, the effect of heat exchanger can only occur around the peripheral surfaces of the section of the supply pipe which is in contact with the heat-dissipating fin. Since the contacting surface is rather small, the hot working liquid may not be completely cooled while passing the supply pipe. The cooling efficiency of the liquid cooling system can be further improved.

### SUMMARY

Accordingly, what is needed is a liquid cooling device which has an enhanced cooling performance.

A liquid cooling device in accordance with a preferred embodiment of the present invention comprises a hollow heat absorbing unit containing liquid therein, a first heat exchange body and a second heat exchange body. The first heat exchange body defines isolated first and second rooms therein. The second heat exchange body defines flow-communicated first and second chambers therein. The first chamber is communicated to the first room, and the second chamber is communicated to the second room. The liquid cooling device further comprises a pump flow-connected between the heat absorbing unit and the second room, and a pipe flow-communicating the heat absorbing unit and the first room. The pump drives the liquid to flow from the heat absorbing unit into the first room, leave the first room into the second chamber via the first chamber, leave the second chamber into the pump via the second room and finally leave the second room and return to the heat absorbing unit.

Other advantages and novel features of the present invention will become more apparent from the following detailed description when taken in conjunction with the accompanying drawings, in which:

### BRIEF DESCRIPTION OF THE DRAWINGS

FIG. 1 is an assembled, isometric view of a liquid cooling device in accordance with a preferred embodiment of the present invention;

FIG. 2 is an exploded, isometric view of a heat exchanger of the liquid cooling device of FIG. 1;

FIG. 3 is similar to FIG. 2, but viewed from another aspect;

FIG. 4 is similar to FIG. 1, with a part being cut away to more clearly show an inner structure of a first heat exchange body of the heat exchanger; and

FIG. 5 is an isometric view of the heat exchanger of the liquid cooling device of FIG. 1, but viewed from another aspect, and having a part of the heat exchanger being cut away to more clearly show an inner structure of a second heat exchange body of the heat exchanger.

### DETAILED DESCRIPTION OF THE INVENTION

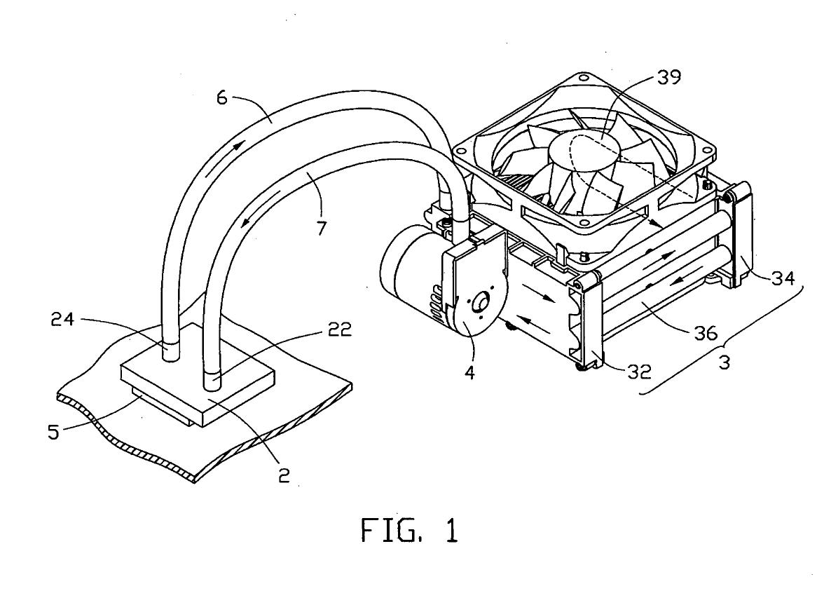

Referring to FIG. 1, a liquid cooling device in accordance with a preferred embodiment of the present invention comprises a hollow heat absorbing unit 2, a heat exchanger 3, a pump 4 communicated to the heat exchanger 3.

The heat absorbing unit 2 has a bottom surface in thermal contact with a top surface of a heat generating component 5. The heat absorbing unit 2 defines an inner space (not labeled) containing an amount of liquid therein. The liquid may be water, automotive radiator liquid, or some other liquid capable of transferring heat. The heat absorbing unit 2 further comprises an inlet 22 and an outlet 24 both in communication with the inner space. A first pipe 6 connects the outlet 24 of the heat absorbing unit 2 to the heat exchanger 3, and a second pipe 7 connects the inlet 22 of the heat absorbing unit 2 to the pump 4.

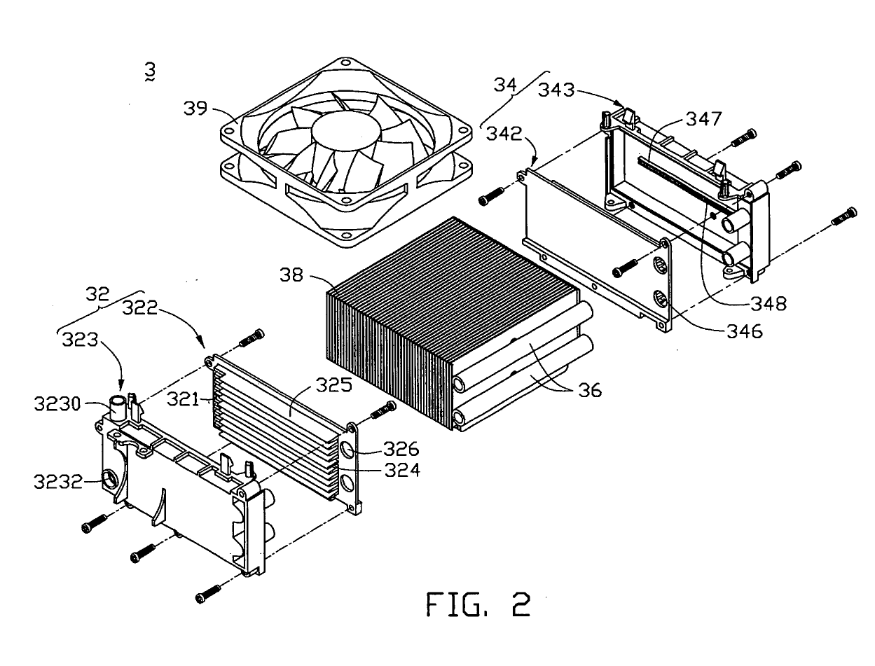

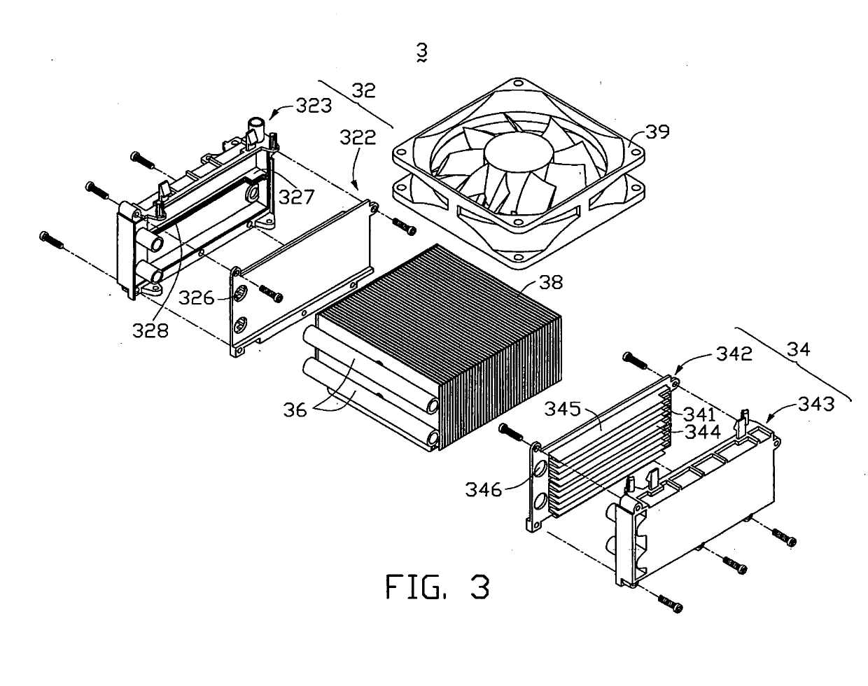

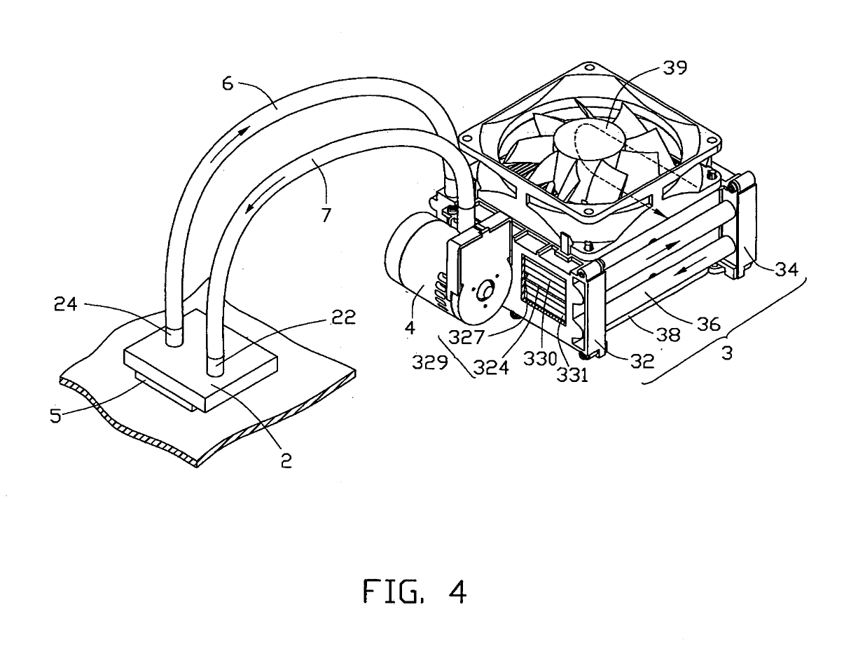

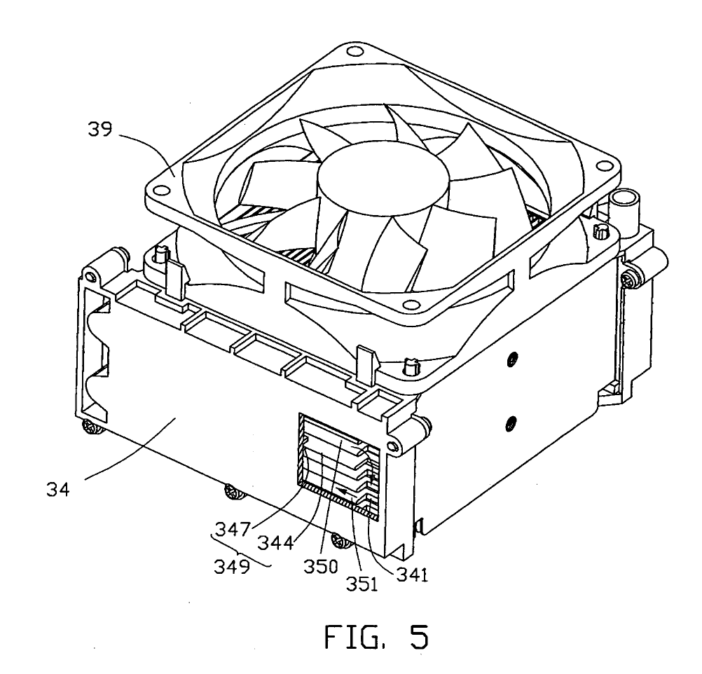

Referring to FIGS. 2-5, the heat exchanger 3 comprises a first heat exchange body 32, a second heat exchange body 34 parallel to the first heat exchange body 32 and communicated to the first heat exchange body 32 through two tubes 36, a plurality of fins 38 sandwiched by the first and second bodies 32, 34, and a fan 39 mounted on the fins 38. Each fin 38 has a thickness gradually becoming thinner along air flow direction so that a uniform temperature distribution in the fins 38 is achieved and air resistance is lowered. The air flow is generated by the fan 39 toward a bottom of the fins 38. Thus, the fin 38 in the preferred embodiment has the smallest thickness at the bottom thereof. However, a fin having a substantially uniform thickness may likewise be utilized.

The first heat exchange body 32 comprises a first plate 322 in thermal contact with one side of the cooling fins 38, and a first cover 323 coupled to the first plate 322, thereby forming a room in the first body 32. An inlet 3230 is formed on one surface of the first cover 323 and is coupled to the first pipe 6. An outlet 3232 is formed at another surface of the first cover 323, capable of being in communication with the pump 4. Five screws (not labeled) are used for coupling the first plate 322 and the first cover 323 together.

A first spacing plate 324 extends perpendicularly from a middle of the first plate 322. A plurality of parallel, equidistant first heat exchange fins 325 is arranged on the first plate 322, at opposite sides of the first spacing plate 324. However, as used herein, the term “fins” is intended to include various other surface configurations that provide increased surface area for heat exchange between the liquid and the first body 32. A first cutout 321 is defined in a common end of the first spacing plate 324 and the first heat exchange fins 325. A pair of first through holes 326 communicating with one ends of the tubes 36 is defined in the first plate 322 at a side thereof opposite the cutout 321, and respectively above and below the first spacing plate 324. The first through holes 326 are provided for connecting the tubs 36 to the first heat exchange body 32.

A first sealing plate 327 extends perpendicularly, rearwards from a middle of a rear face of the first cover 323 and defines a first groove 328 therein. The first sealing plate 327 has a rear projection (not labeled) at an end thereof. The rear projection is located and has a width corresponding to that of the first cutout 321.

When assembling the first cover 323 to the first plate 322, the first spacing plate 324 is received in the first groove 328, thus forming a first internal divider wall 329. The first internal divider wall 329 substantially divides the room in the first body 32 into first and second rooms 330, 331 isolated from each other.

Similar to the first heat exchange body 32, the second heat exchange body 34 comprises a second plate 342 and a second cover 343 coupled to the second plate 342, thereby forming a chamber in the second heat exchange body 34. Five screws (not labeled) are used for coupling the second cover 343 and the second plate 342 together. A second spacing plate 344 extends from a middle of the second plate 342, and a plurality of second heat exchange fins 345 is arranged on the second plate 342 above and below the second spacing plate 344. A second cutout 341 is defined in a common end of the second spacing plate 344 and the second heat exchange fins 345. A pair of second through holes 346 communicating with the other ends of the tubes 36 is defined in the second plate 322 at a side thereof opposite the cutout 341, and respectively above and below the second spacing plate 344. The second through holes 346 are provided for connecting the tubes 36 to the second heat exchange body 34.

A second sealing plate 347 extends perpendicularly, forwardly from a middle of the second cover 343 and forms a second groove 348 therein. When assembling the second cover 343 to the second plate 342, the second spacing plate 344 is received in the second groove 348, thus forming a second internal divider wall 349. The second internal divider wall 349 substantially divides the chamber in the second heat exchange body 34 into first and second chambers 350, 351 communicating with each other. The first chamber 350 is communicated to the first room 330 through upper one of the tubes 36, and the second chamber 351 is communicated to the second room 331 through lower one of the tubes 36.

In operation of the liquid cooling device, the liquid in the absorbing unit 2 absorbs heat from the heat generating component 5 and then flows at the direction shown by arrows of FIG. 1. At first, the heated liquid travels into the first room 330 of the first body 32 through the first pipe 6, then flows into the first chamber 350 of the second body 34 through the upper tube 36, and then goes through second cutout 341 into the second chamber 351. Subsequently, the liquid flows into the second room 331 through the lower tube 36 and finally returns to the heat absorbing unit 2 by the action of the pump 4 for another circulation in a sequence as mention above.

During the circulation of the liquid, the heated liquid conducts the heat originating from the heat generating component 5 to the first heat exchange body 32 and the second heat exchange body 34. Then the heat absorbed by the first heat exchange body 32 and the second heat exchange body 34 is dissipated by the fins 8 and the fan 39. The heat exchange area between the liquid and the first and second heat exchange bodies 32,34 is increased by means of the first and second heat exchange fins 325, 345, so that the heated liquid may be completely cooled after passing the first and second bodies 32,34. Thus, the circulation of the liquid can continuously take away the heat generated by the heat generating component 5.

As shown in FIG. 1, the hot liquid which is heated up in the heat absorbing unit 2 directly travels into the heat exchanger 3 through the first pipe 6, and the hot liquid is cooled down in the heat exchanger 3. Before the cooled liquid flows back to the heat absorbing unit 2, the cooled liquid is pumped into the pump 4. The pump 4 is also cooled down by the cooled liquid, and the reliability and life of the pump 4 are both improved. Thus, the circulation route of the liquid can improves the reliability and life of the liquid cooling device.

It is believed that the present invention and its advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

We claim:

1. A liquid cooling device comprising:
a hollow heat absorbing unit containing liquid therein;
a first heat exchange body defining isolated first and second rooms therein;
a second heat exchange body defining flow-communicated first and second chambers therein, the first chamber being communicated to the first room, the second chamber being communicated to the second room;
a pump fluidly connected between the heat absorbing unit and the second room; and
a pipe fluidly connecting the heat absorbing unit and the first room.

2. The liquid cooling device as claimed in claim 1, further comprising a plurality of fins thermally engaged with the first and second heat exchange bodies.

3. The liquid cooling device as claimed in claim 2, wherein a thickness of each of the fins gradually becomes thinner along a direction of an air flow through the fins.

4. The liquid cooling device as claimed in claim 1, wherein the first and second chambers communicates with the corresponding first and second rooms through two tubes respectively.

5. The liquid cooling device as claimed in claim 1, wherein the first heat exchange body comprises a first plate, a first cover coupled to the first plate thereby forming a room in the first body, and a first divider wall dividing the room into two parts to form the first and second rooms.

6. The liquid cooling device as claimed in claim 5, wherein the second body comprises a second plate, a second cover coupled to the second plate thereby forming a chamber in the second body, and a second divider wall dividing the chamber into two parts to form the first chamber and the second chamber.

7. The liquid cooling device as claimed in claim 6, wherein each of the first and the second divider walls comprises a spacing plate extending perpendicularly from each of the first and second plates, and a sealing plate extending perpendicularly from each of the first and second covers and receiving the spacing plate therein.

8. The liquid cooling device as claimed in claim 7, wherein a plurality of heat exchange fins is arranged in each of the first and second rooms and first and second chambers.

9. The liquid cooling device as claimed in claim 1, wherein the first and second heat exchange bodies are parallel with each other.

10. The liquid cooling device as claimed in claim 1, further comprising a fan mounted on the fins.

11. A liquid cooling device comprising:
a hollow heat absorbing unit containing liquid therein, and the heat absorbing unit thermally contacting a heat generating component;
a fist heat exchange body defining isolated first and second rooms therein;
a second heat exchange body; and
a pump;
wherein the liquid heated up in the heat absorbing unit flows through the first room, the second heat exchange body and the second room in turn so that the liquid conducts heat originating from the heat generating component to the first and second heat exchange bodies, then the pump draws the liquid from the second room back into the heat absorbing unit for another circulation.

12. The liquid cooling device as claimed in claim 11, wherein the second heat exchange body defines first and second chambers therein, which are fluidly communicated with each other, the liquid leaving the first room into the second heat exchange body being into the first chamber of the second heat exchange body and leaving the first chamber into the second room of the first heat exchange body via the second chamber of the second heat exchange body.

13. The liquid cooling device as claimed in claim 11, further comprising a plurality of fins mounted between the first and second heat exchange bodies and thermally contacting therewith.

14. The liquid cooling device as claimed in claim 13, further comprising a fan mounted on the fins.

15. The liquid cooling device as claimed in claim 11, wherein a plurality of heat exchange fins is arranged in each of the first and second heat exchange bodies to increase heat exchange area between the liquid and the first and second heat exchange bodies.

16. A liquid cooling device for cooling a heat generating component, comprising:
a heat absorbing unit thermally contacting with the heat generating component and receiving liquid therein;
a first heat exchange body;
a second heat exchange body;
a plurality of fins mounted between the first and second heat exchange bodies and thermally contacting therewith; and
a pump for driving the liquid received in the heat absorbing unit and heated by the heat absorbing unit to move with following sequence: first leaving the heat absorbing unit into the first heat exchanger body, then leaving the first heat exchange body into the second heat exchange body, thereafter leaving the second heat exchange body into the first heat exchange body, and finally leaving the first heat exchange body and returning the heat absorbing unit.

17. The liquid cooling device of claim 16, wherein the first heat exchange body forms first and second rooms therein, which are fluidly isolated from each other and the second heat exchange body forms first and second chambers therein, which are fluidly communicated with each other, the heated liquid leaving the heat absorbing unit into the first heat exchange body being into the first room of the first heat exchange body and the heated liquid leaving the first heat exchange body and returning the heat absorbing unit being leaving the second room of the first heat exchange body.

18. The liquid cooling device of claim 17, further comprising an electric fan generating a forced air flow through the fins along a direction, thickness of each of the fin being gradually reduced along the direction.

19. The liquid cooling device of claim 17, wherein each of the first, second rooms and first and second chambers comprise a heat exchange fin therein.

20. The liquid cooling device of claim 17, wherein the heated liquid leaving the second room of the first heat exchange body and returning to the heat absorbing unit flows through the pump.
